(19) United States
(12) Patent Application Publication
(10) Pub. No.: US 2017/0023612 A1
(43) Pub. Date: Jan. 26, 2017

(54) Meter Box Lid

(71) Applicant: Iometers, LLC, Addison, TX (US)

(72) Inventor: Scott Brown, Addison, TX (US)

(21) Appl. No.: 15/217,485

(22) Filed: Jul. 22, 2016

Related U.S. Application Data
(60) Provisional application No. 62/195,570, filed on Jul. 22, 2015.

(51) Int. Cl. G01R 1/04; G01R 21/00; H04Q 9/00; G01D 4/00

(52) U.S. Cl. CPC G01R 1/04; G01D 4/004; G01R 21/00; H04Q 9/00; H04Q 2209/88

(57) ABSTRACT

A meter box lid includes electronic meter reading equipment that may be disposed in areas of the meter box lid, so as to prevent the equipment from becoming damaged when the lid is removed. A transmitter antenna may be mounted to the meter box lid to deliver a signal to data collection device and may remain intact whether or not the meter box lid is removed from a meter box. A solar panel may provide an extended battery life, and a tamper switch may provide notification of removal of the meter box lid.

### CROSS REFERENCE TO RELATED APPLICATION

The present application claims priority to U.S. Patent Application No. 62/195,570 filed Jul. 22, 2015, entitled “METER BOX LID,” which is incorporated herein by reference in its entirety.

### TECHNICAL FIELD

The disclosure relates generally to meter box assemblies used to house electronic meter reading equipment. In particular, the disclosure relates to meter box assemblies for public utilities or similar applications.

### BACKGROUND

Meter box assemblies are used in public electric and water systems to provide a vehicle for frequently reading electric consumption and water consumption of residences and businesses. The ability to frequently read meters provides a means of closely monitoring consumption so that utility service billing may become more accurate. Historically, utility meters have been located outside of buildings or along roadsides. These utility meters have been buried at ground level or at a shallow underground depth near residences and businesses that require utility services. Further, utility meters have been housed inside of protective enclosures, often bottomless, which typically include a vault or housing and a cover or lid. Generally, the cover or lid is disposed at or near the ground surface to provide easy access to underlying utility meter equipment.

For many years, utility meters have also included analog and digital displays that can be visually read by an employee of a utility company by lifting the lid from the meter box. In recent years, these utility meters have been equipped with electronic meter reading equipment that enables utility providers to more easily collect consumption data. Today, modern electronic meter reading equipment is generally incorporated into utility meters as one of two types, both types including a transmitter in hard-wired communication with a metering device connected in-line to a water conduit. The first type of electronic meter reading equipment transmits a signal, such as by radio frequency, to a remote data collection device that may be stationary or mobile, for example, a remote data collection device mounted into a truck. The second type of electronic meter reading equipment transmits a signal to a handheld device through contact, commonly known as a touch read system. In all known meter box assemblies and systems, electronic equipment is formed as part of the meter or attached to the lid of the meter box. As such, problems occur when meter box lids are removed to provide access to internal meter box equipment. Further, electronic equipment attached to the lid can become damaged when employees do not carefully rest the meter box lid on the ground after removing the lid, and/or fail to exercise caution when removing or replacing the lid. It is estimated that in many large utility systems, up to 20% of electronic meter reading equipment is non-functional, at any given time, due to improper handling.

### SUMMARY

Embodiments of the present disclosure may provide a meter box lid including electronic meter reading equipment that may protect the equipment from damage, in particular, a meter box lid that may include a transmitter that may deliver a signal to a data collection device. Embodiments of the present disclosure also may provide a transmitter that may be formed as part of the meter box lid and may be safely removed from the meter box. Further, a meter box lid according to embodiments of the present disclosure may include a tamper switch. The tamper switch may instantly notify a utility company when a meter box lid is opened or removed from the meter box. Additionally, a solar panel may be provided according to embodiments of the present disclosure that may be mounted, formed or attached to the top of the meter box lid, thereby providing extended battery life to the transmitter. It is an object of the present disclosure to provide access for service or maintenance of internal utility equipment, and a utility meter that may not expose the transmitter to damage.

An embodiment of the present disclosure may provide a meter box lid that may include a top side that may be arranged to face away from a meter box. The top side may include a solar panel that may be mounted, formed, or attached to the top side. A transmitter antenna may be mounted below the solar panel on the top side, and the transmitter antenna may be removable, arranged to deliver a signal to a data collection device, and may be arranged to automatically read a meter. The meter box lid may include a bottom side that may be arranged to close the meter box. The bottom side may include a battery pack that may be mounted in a portion of the bottom side, and may include utility equipment that may be mounted via opposite sidewalls of the bottom side. The transmitter antenna may have a ground plate and a radiator plate that may be stacked above the ground plate. The solar panel may be disposed in a cutout of a holder of the top side and may maintain a flat surface of the top side. The flat surface may be proximate the solar panel in a mounted position and may be free of any protrusions. A tamper switch may be disposed in an outer lip of the meter box lid. A transmitter board may be connected to the tamper switch via a plurality of connection wires. A tamper switch may be disposed on the top side or the bottom side of the meter box lid. A tamper switch may be configured to provide a notification when the meter box lid is displaced from the meter box. The solar panel may extend a battery life of the transmitter antenna. The solar panel may extend the battery life of the transmitter antenna by at least 50 percent. The solar panel may be a rectangular shape or a circular shape. The transmitter antenna may include a transmitter that may be an epoxy applied over the transmitter antenna and the solar panel. The transmitter antenna may be disposed in a cutout of a holder of the top side and may maintain a flat surface of the top side. The flat surface may be proximate the transmitter antenna in a mounted position and may be free of any protrusions.

An embodiment of the present disclosure may provide a meter box assembly that may include a meter box lid, and the meter box lid may be a transmitter. The meter box assembly may further include a solar panel that may be mounted to a top side of the meter box lid, and a transmitter antenna that may be mounted below the solar panel. Utility equipment, a tamper switch, and a battery pack may be disposed in the meter box lid. The meter box assembly may include a bottom side that may be arranged to close the meter box assembly. A latch system may be provided underneath the bottom side and may secure a cover to the bottom side. The cover may tightly close and may protect contents of the bottom side. The cover may include a smooth surface and may provide the meter box assembly with the ability to lie flay against a resting surface. The solar panel may be disposed in a cutout of a holder of the top of the meter box lid and may maintain a flat surface of the top. The flat surface may be proximate the solar panel in a mounted position and may be free of any protrusions. The transmitter antenna may be disposed in a cutout of a holder of the top of the meter box lid and may maintain a flat surface of the top. The flat surface may be proximate the transmitter antenna in a mounted position and may be free of any protrusions. The transmitter antenna may be mounted below the solar panel on the top of the meter box lid, may be removable, may be arranged to deliver a signal to a data collection device, and may automatically read a meter. The solar panel may extend a battery life of the transmitter antenna. The tamper switch may be configured to provide a notification when the meter box lid is displaced from the meter box assembly.

Other technical features may be readily apparent to one skilled in the art from the following drawings, descriptions and claims.

### BRIEF DESCRIPTION OF THE DRAWINGS

For a more complete understanding of this disclosure and its features, reference is now made to the following description, taken in conjunction with the accompanying drawings, in which:

FIG. 1 depicts a perspective view of the top side of a meter box lid according to an embodiment of the present disclosure;

FIG. 2 depicts a perspective view of the bottom side of a closed meter box lid according to an embodiment of the present disclosure;

FIG. 3 depicts an exploded perspective view of the bottom side of a meter box lid according to an embodiment of the present disclosure;

FIG. 4 depicts a perspective view of the bottom side of a meter box lid including an open battery pack according to an embodiment of the present disclosure;

FIG. 5 depicts a perspective view of the top side of a meter box lid including an exploded view of a solar panel according to an embodiment of the present disclosure;

FIG. 6 depicts a perspective view of a closed battery pack according to an embodiment of the present disclosure;

FIG. 7 depicts a perspective view of an open battery pack according to an embodiment of the present disclosure;

FIG. 8 depicts a perspective view of the bottom side of a meter box lid including an open battery pack according to an embodiment of the present disclosure;

FIG. 9 depicts a perspective view of a meter box lid including an exploded view of a solar panel according to an embodiment of the present disclosure;

FIG. 10 depicts a perspective view of the bottom side of a meter box lid according to an embodiment of the present disclosure;

FIG. 11 depicts a perspective view of the bottom side of a meter box lid including an exploded view of a battery pack according to an embodiment of the present disclosure;

FIG. 12 depicts a perspective view of a meter box lid including an exploded view of an open battery pack according to an embodiment of the present disclosure;

FIG. 13 depicts a perspective view of the bottom side of a closed meter box lid including an exploded view of a tamper switch and connection wires according to an embodiment of the present disclosure; and

FIG. 14 depicts a perspective view of the bottom side of an open meter box lid including an exploded view of a cover according to an embodiment of the present disclosure.

### DETAILED DESCRIPTION

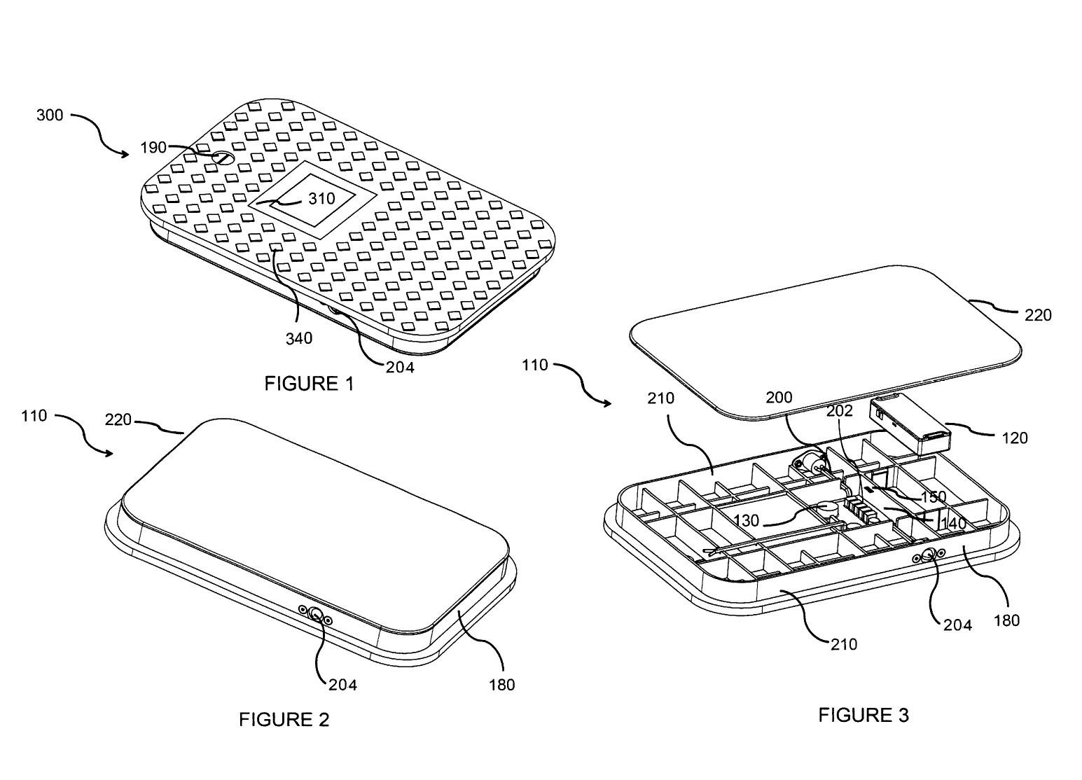

The present disclosure generally provides a meter box lid including bottom side 110 (FIG. 2) and top side 300 (FIG. 1), for housing meter reading equipment that may include solar panel 310 (FIG. 1), battery pack 120 (FIG. 3), connection tabs 150 (FIG. 3), and utility equipment 130 (FIG. 3). The meter box may be arranged to protect and extend the lifetime of meter reading equipment and meter box contents.

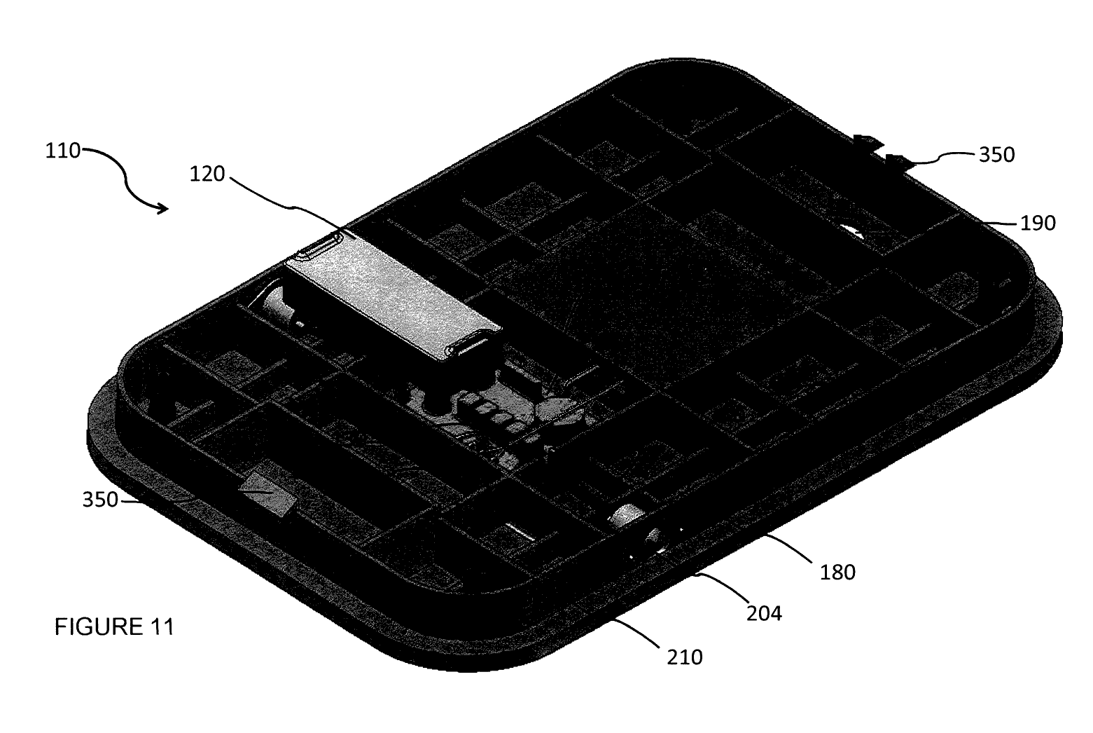

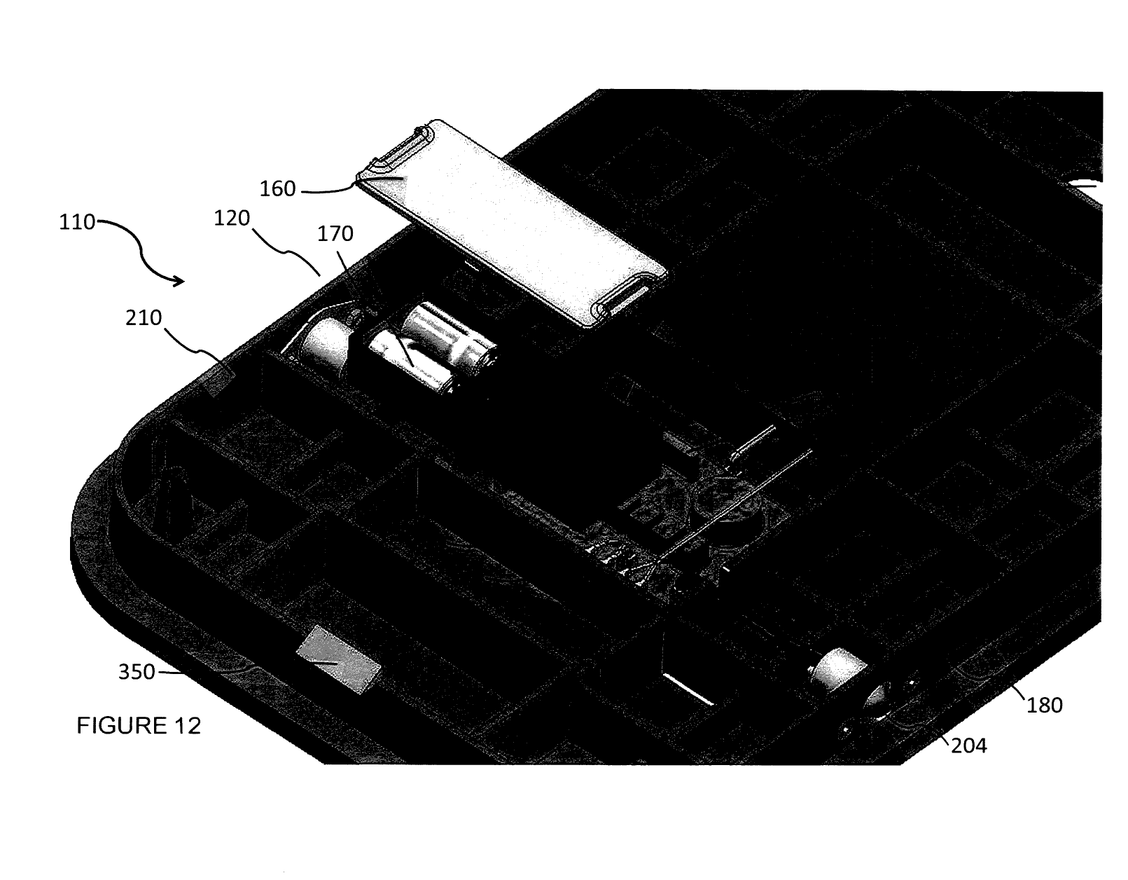

As shown in FIGS. 1, 5, and 9 according to an embodiment of the present disclosure, the meter box lid may include top side 300 facing away from the meter box (not shown). Top side 300 of the meter box lid may generally be exposed to an outside environment including, but not limited to, sand, soil, rocks, and objects that may contact top side of the meter box lid, as a result of weather conditions and environmental influence. In an embodiment of the present disclosure, top side 300 may include textured surface 340 that may improve the ability to open a meter box and provide aesthetic value. Solar panel 310 may be mounted, formed or attached to top side 300 of the meter box. Solar panel 310 may be placed at a center portion of the meter box so that solar panel 310 may be located at a point equal distance from all sides of the meter box; however, there may be other embodiments of the present disclosure where solar panel 310 is not placed in the center portion without departing from the present disclosure. Further, solar panel 310 may be located in a portion of top side 300 of the meter box where cut out, hole or depression for holder 320 may be formed, as shown in FIGS. 5 and 11 according to embodiment of the present disclosure, so as to receive solar panel 310 and maintain a flat top side free of any protrusions within the area where solar panel 310 may be mounted. In an embodiment of the present disclosure, solar panel 310 may have a rectangular shape that may be three inches by three inches (3″×3″) or a circular shape with a diameter of 2 inches (2″). Additionally, in an embodiment of the present disclosure, solar panel 310 may extend the lifetime of batteries 170 (FIG. 12) that may be mounted in the meter box. In an embodiment of the present disclosure, solar panel may extend battery life by approximately 65.3 percent; however, the percentage may change without departing from the present disclosure. It should be appreciated that solar panel 310 may not be limited in shape, size, and placement on the meter box lid. It should also be appreciated that top side 300 of the meter box may be composed of any material including, but not limited to, metal, plastic, concrete or a concrete/polymer composite. Further, it should be appreciated that top side 300 of the meter box may have any shape, size, and weight without departing from the present disclosure.

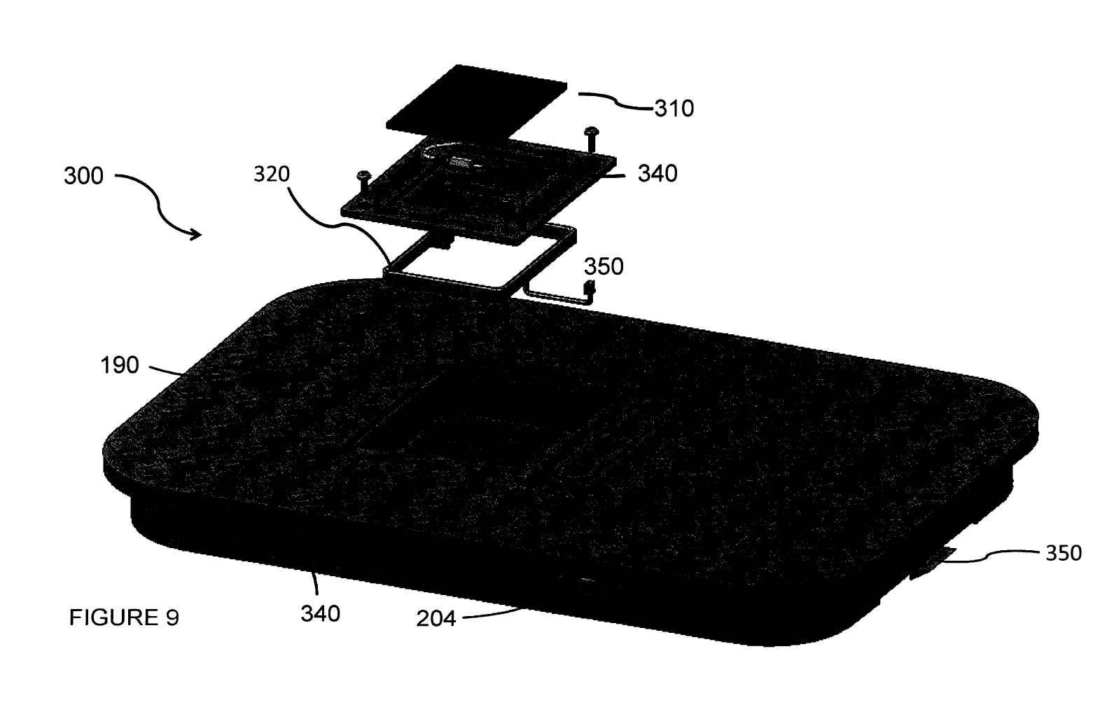

Referring to FIG. 9 according to an embodiment of the present disclosure, top side 300 of the meter box may include transmitter antenna 350 that may be mounted below solar panel 310 inside of holder 320. Connector 330 may also be mounted inside holder 320 and provide an attachment point for solar panel wire 340. Transmitter antenna 350 may be mounted in a cut out, hole or depression of holder 320 directly below solar panel 310 so that top side 300 of the meter box maintains a flat surface. Further, transmitter antenna 350 may be removable and arranged to automatically read a meter. In an embodiment of the present disclosure, transmitter antenna 350 may include a ground plate and a radiator plate stacked above the ground plate. In an embodiment of the present disclosure, transmitter antenna 350 may include an epoxy applied over both transmitter antenna 350 and solar panel 310. Further, transmitter antenna 350 may be arranged to deliver a signal to a data collection device. It should be appreciated that the epoxy may be clear in color; however, the epoxy may include some coloration without departing from the present disclosure. It should also be appreciated that the epoxy may be selected from any thermally conductive adhesive.

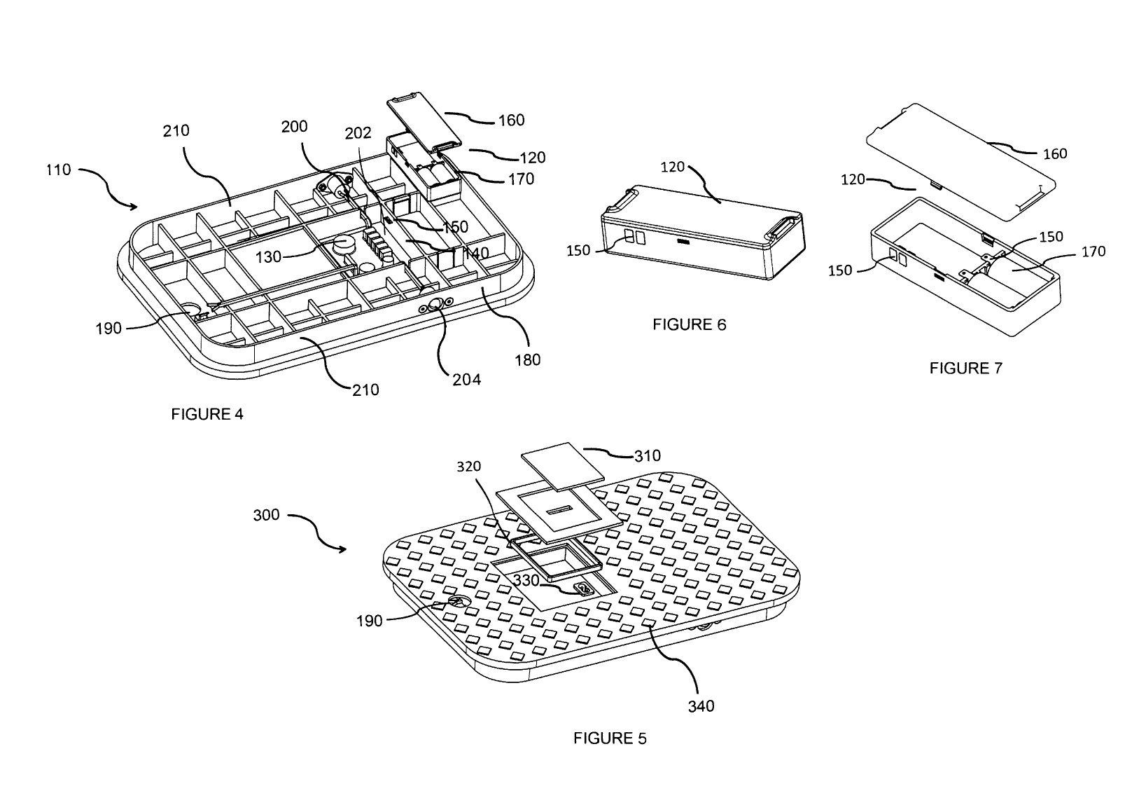

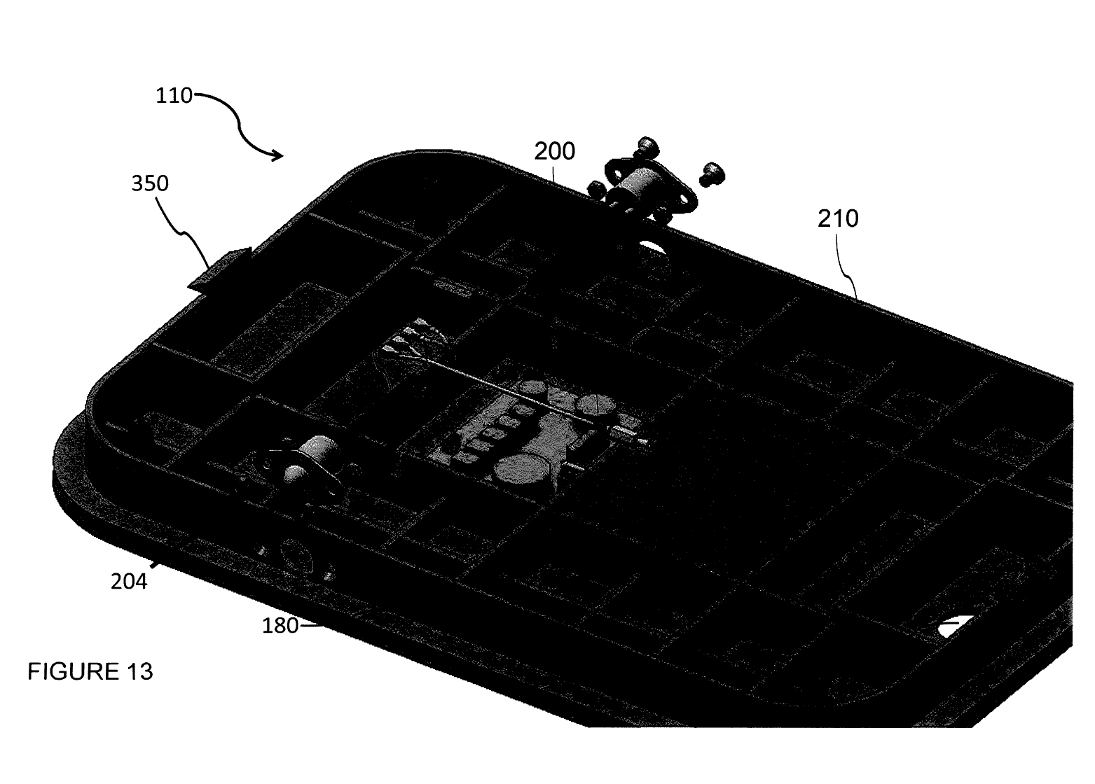

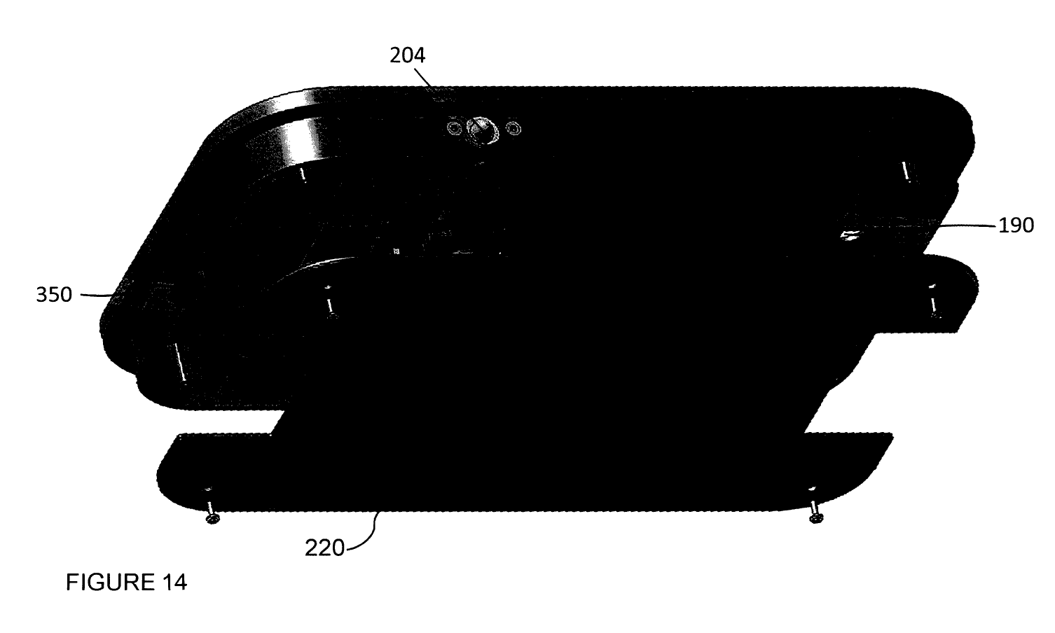

As shown in FIGS. 1, 5, and 9 according to an embodiment of the present disclosure, top side 300 of the meter box may include through-hole 190. FIGS. 4, 8, and 11-14 depict bottom side 110 including through-hole 190. It should be appreciated that both bottom side 110 and top side 300 may include through-hole 190, and through-hole 190 may be located in an identical location and with identical dimensions on bottom side 110 and top side 300 to create one passageway that may provide a grasping member for opening and closing the meter box. Further, through-hole 190 may have any shape or size and may be located anywhere along the meter box. It should be appreciated that the meter box may include any type or form of grasping member for opening and closing the meter box including, but not limited to, handles, clasps, screws, and locks.

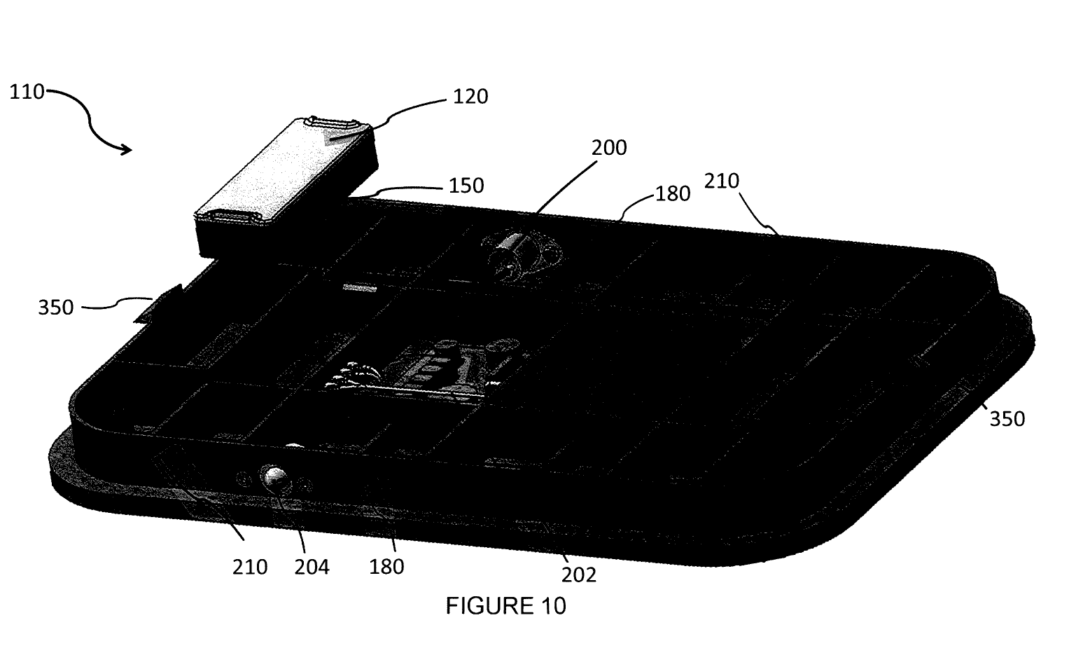

As shown in FIGS. 3-4 and 10-13, in an embodiment of the present disclosure, bottom side 100 may include transmitter board 202, at least one tamper switch 204, and connection wires 200. Tamper switch 204 may provide a notification or an alert when the meter box lid is displaced from the meter box. Displacement of the meter box lid from the meter box may include partial displacement or complete removal from the meter box. In an embodiment of the present disclosure, tamper switch 204 may be disposed in outer lips 210 of the meter box. It should be appreciated that tamper switch 204 may be located at any position along the meter box without departing from the present disclosure. It should also be appreciated that tamper switch 204 may be selected from any type of tamper switch including, but not limited to, a roller-ball switch, a snap-in switch, and a magnetic switch.

Still referring to FIGS. 3-4, 8, and 10-13 according to an embodiment of the present disclosure, the meter box lid may include bottom side 110 and electronic meter reading equipment. Bottom side 110 may include outer lip 180, such that outer lip 180 may have a depth thick enough to hold the meter reading equipment and tightly seal the inside of the meter box (not shown). The inside of the meter box may receive bottom side 110, such that the meter box may easily detach and attach to meter box 102. As such, both the contents of bottom side 110 and the contents of the meter box may be protected from damage, debris, and improper handling of the meter box. It should be appreciated that bottom side 110 may include any desired number of inner lips, compartments, sections or walls. It should also be appreciated that bottom side 110 may be composed of any material including, but not limited to, metal, plastic, concrete or a concrete/polymer composite. It should further be appreciated that bottom side 110 may have any shape, size, and weight.

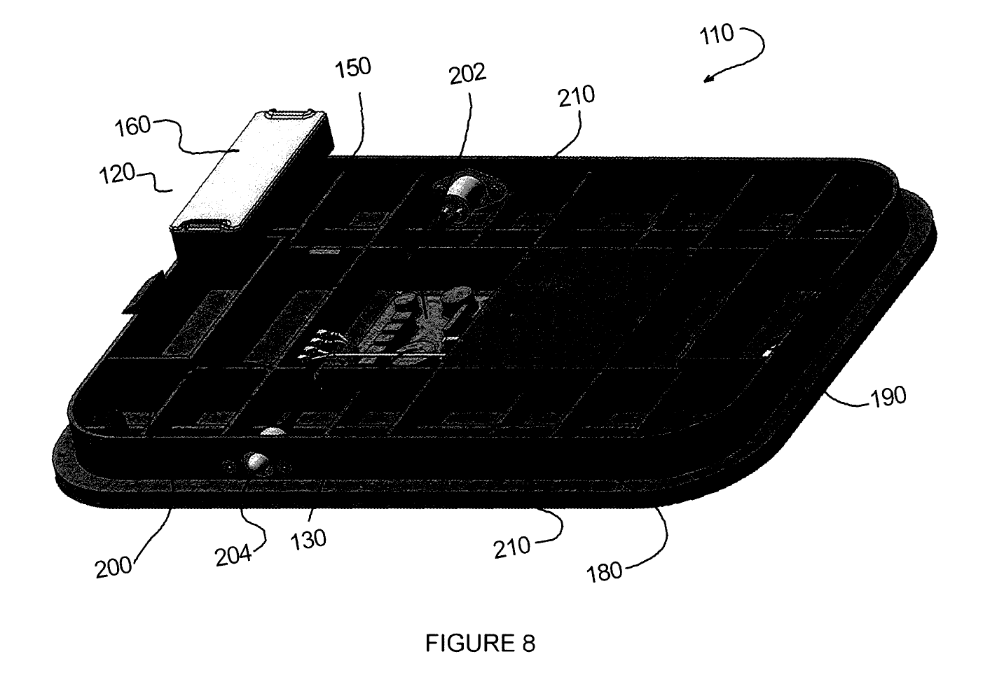

FIGS. 3, 4, 8, and 10-12 depict a perspective view of the meter box according to an embodiment of the present disclosure. As shown in FIGS. 3, 4, 8, and 10-12 according to an embodiment of the present disclosure, the meter box may include battery pack 120 that may be arranged inside of a compartment, section, or between sidewalls 210 of bottom side 110. Battery pack 120, as shown in FIGS. 6, 7, and 12 according to an embodiment of the present disclosure, may include batteries 170, connection tabs 150, and cover 160 positioned to secure batteries 170 inside of battery pack 120. It should be appreciated that connection tabs 150 may be mounted at any location on the meter box including, but not limited to, inner lip 140, any inner wall of bottom side 110, and inside battery pack 120. It should further be appreciated that any number of batteries and any type of battery may be included in battery pack 120. As further shown in FIGS. 8 and 10-13 according to an embodiment of the present disclosure, utility equipment 130 may be mounted to bottom side 110. In an embodiment of the present disclosure, utility equipment 130 may be mounted to bottom side 110 and connection wires 200 may attach to opposite sidewalls 210 of bottom side 110, as shown in FIGS. 3, 4, 8, and 10-13 according to an embodiment of the present disclosure. Further, transmitter board 202 may be connected to at least one tamper switch 204 via connection wires 200. It should be appreciated that any mounting components and hardware may be used to securely attach utility equipment 130 to bottom side 110.

As shown in FIGS. 2, 3, and 14 according to an embodiment of the present disclosure, it should be appreciated that cover 220, located underneath bottom side 110, may tightly close and protect the contents of bottom side 110 and the meter box. It should further be appreciated that cover 220 may have a smooth surface that may provide the meter box with the ability to lie flat against a resting surface.

As shown in FIGS. 8-14 according to an embodiment of the present disclosure, the meter box may include latch system 350 that may be located underneath bottom side 110 for securing cover 220 (FIGS. 2, 3 and 14) to bottom side 110. It should be appreciated that latch system 350 may include any number of latches to lock cover 220 onto the underside of bottom side 110. It should further be appreciated that latch system may include latches of any shape and size.

In an embodiment of the present disclosure, grade level or subsurface protective enclosures may be referred to as meter boxes, grade level enclosures, underground enclosures, pull boxes, pit boxes, valve boxes, splice boxes and junction boxes. It should be appreciated that meter boxes may be composed of various materials, including, but not limited to, metal, plastic, concrete or a concrete/polymer composite. It should also be appreciated that meter boxes and meter box lids vary greatly in weight ranging, as a non-limiting example, from approximately five to 500 pounds, depending on the size of the meter box and/or the material composition of the meter box and meter box lid.

It may be advantageous to set forth definitions of certain words and phrases used in this patent document. For the purposes of the discussion herein, the terms “electronic meter reading equipment,” “utility equipment,” and “transmitter means” encompass any type of meter reading device including, but not limited to, remote devices, stationary devices, and handheld devices. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A meter box lid, comprising:
a top side arranged to face away from a meter box, comprising:
a solar panel mounted, formed, or attached to the top side; and
a transmitter antenna mounted below the solar panel on the top side, wherein the transmitter antenna is removable, arranged to deliver a signal to a data collection device, and automatically reads a meter; and
a bottom side arranged to close the meter box, comprising:
a battery pack mounted in a portion of the bottom side; and
utility equipment mounted via opposite sidewalls of the bottom side.

2. The meter box lid of claim 1, wherein the transmitter antenna has a ground plate and a radiator plate stacked above the ground plate.

3. The meter box lid of claim 1, wherein the solar panel is disposed in a cutout of a holder of the top side to maintain a flat surface of the top side, and wherein the flat surface is proximate the solar panel in a mounted position and free of any protrusions.

4. The meter box lid of claim 1, further comprising:
a tamper switch disposed in an outer lip of the meter box lid.

5. The meter box lid of claim 4, further comprising:
a transmitter board connected to the tamper switch via a plurality of connection wires.

6. The meter box lid of claim 1, further comprising:
a tamper switch disposed on the top side or the bottom side of the meter box lid.

7. The meter box lid of claim 1, further comprising:
a tamper switch configured to provide a notification when the meter box lid is displaced from the meter box.

8. The meter box lid of claim 1, wherein the solar panel extends a battery life of the transmitter antenna.

9. The meter box lid of claim 8, wherein the solar panel extends the battery life of the transmitter antenna by at least 50 percent.

10. The meter box lid of claim 1, wherein the solar panel is a rectangular shape or a circular shape.

11. The meter box lid of claim 1, wherein the transmitter antenna includes a transmitter that is an epoxy applied over the transmitter antenna and the solar panel.

12. The meter box lid of claim 1, wherein the transmitter antenna is disposed in a cutout of a holder of the top side to maintain a flat surface of the top side, and wherein the flat surface is proximate the transmitter antenna in a mounted position and free of any protrusions.

13. A meter box assembly, comprising:
a meter box lid, wherein the meter box lid is a transmitter;
a solar panel mounted to a top of the meter box lid;
a transmitter antenna mounted below the solar panel;
utility equipment disposed in the meter box lid;
a tamper switch disposed in the meter box lid; and
a battery pack disposed in the meter box lid.

14. The meter box assembly of claim 13, further comprising:
a bottom side arranged to close the meter box assembly; and
a latch system provided underneath the bottom side to secure a cover to the bottom side, wherein the cover tightly closes and protects contents of the bottom side.

15. The meter box assembly of claim 14, wherein the cover includes a smooth surface and provides the meter box assembly with the ability to lie flay against a resting surface.

16. The meter box assembly of claim 13, wherein the solar panel is disposed in a cutout of a holder of the top of the meter box lid to maintain a flat surface of the top, and wherein the flat surface is proximate the solar panel in a mounted position and free of any protrusions.

17. The meter box assembly of claim 13, wherein the transmitter antenna is disposed in a cutout of a holder of the top of the meter box lid to maintain a flat surface of the top, and wherein the flat surface is proximate the transmitter antenna in a mounted position and free of any protrusions.

18. The meter box assembly of claim 13, wherein the transmitter antenna is mounted below the solar panel on the top of the meter box lid, removable, arranged to deliver a signal to a data collection device, and automatically reads a meter.

19. The meter box assembly of claim 13, wherein the solar panel extends a battery life of the transmitter antenna.

20. The meter box assembly of claim 13, wherein the tamper switch is configured to provide a notification when the meter box lid is displaced from the meter box assembly.
